(19) United States
(12) Patent Application Publication
(10) Pub. No.: US 2015/0117483 A1
(43) Pub. Date: Apr. 30, 2015

(54) SEMICONDUCTOR LASER DIODE HAVING AN ADJUSTABLE EMISSION WAVELENGTH

(71) Applicant: nanoplus Nanosystems and Technologies GmbH, Gerbrunn (DE)

(72) Inventors: Johannes KOETH, Gerbrunn (DE); Christian ZIMMERMANN, Erlenbach (DE); Julian SCHEUERMANN, Hochberg (DE)

(21) Appl. No.: 14/522,868

(22) Filed: Oct. 24, 2014

(30) Foreign Application Priority Data
Oct. 25, 2013 (DE) 10 2013 111 770.8
Sep. 22, 2014 (EP) 14185737.5

(51) Int. Cl. H01S 5/02

(52) U.S. Cl. CPC H01S 5/0206
USPC 372/44.01

(57) ABSTRACT

The invention relates to a semiconductor laser diode (01) having a substrate layer, a first doped cladding layer (02) and a second doped cladding layer (09), at least one wave guide (03, 04), an active layer, a cladding layer structure (05) that is adjacent to the active layer or to the at least one wave guide (03, 04), and at least one interdigital transducer (08), wherein the at least one interdigital transducer (08) is adjacent to the cladding layer structure (05) and the cladding layer structure (05) has at least a first area (06) that is realized as a substantially undoped semiconductor layer and has, at least in sections, a second area (07) that is adjacent to the first area (06) at one side and to the interdigital transducer (08) at another side, the second area (07) having a reduced density of free charge carriers as compared to the first area (06).

### FIELD OF INVENTION

The present invention relates to a semiconductor laser diode having an adjustable emission wavelength including the epitaxial and/or lithographic structure of the semiconductor laser diode.

### BACKGROUND

Owing to their finite gain bandwidth, semiconductor lasers have a mode spectrum that contains a plurality of so-called Fabry-Perot modes. The spectral distance of the individual modes is defined by

$$Δ λ = \frac{{λ}^{2}}{2 {n}_{g} L} ,$$

wherein λ is the wavelength, n_{g} is the group index and L is the cavity length of the semiconductor laser diode. For a plurality of applications, such as spectroscopy, telecommunication or meteorology, it is particularly desirable to select individual, well-defined Fabry-Perot modes of the entire mode spectrum as the emission wavelength of a semiconductor laser diode and to operate the semiconductor laser diode in that exact mode and with that exact wavelength. In this context, different methods for producing semiconductor laser diodes and different structures of semiconductor laser diodes are known that allow selecting the emission wavelength.

For instance, in surface-emitting laser diodes, so-called vertical cavity surface emitting lasers (VCSEL), it is possible, by selecting a correspondingly short cavity length, such as 1-3 times the wavelength, for the distance between two adjacent Fabry-Perot modes in these components to be so large that their distance exceeds the gain bandwidth and only one mode within the gain bandwidth has an impact on laser operation.

In contrast, however, edge-emitting lasers, whose cavity length is usually several 100 μm and up to several mm long, have thousands of Fabry-Perot modes in the range of the respective gain bandwidth. To allow restriction of the modes of the emission wavelength and to provide higher spectral purity in these components, different methods for producing corresponding semiconductor laser diodes and different structures resulting therefrom are known as well. For example, feedback mechanisms may be used which may either be integrated monolithically into the semiconductor laser diode or be introduced externally into a beam path of the semiconductor laser diodes.

In the context of monolithic structures of semiconductor laser diodes for mode selection, the co-called distributed feedback (DFB) principle is known, for example, which is based on a periodic modulation of the refractive index and/or the gain in the pumped area of the semiconductor laser diode. Alternatively, so-called distributed Bragg reflector laser diodes (DBR lasers) are known, which exhibit a periodic refractive index modulation in a passive area of the semiconductor laser diode.

Gratings may be employed in the external mode selection of semiconductor laser diodes, the laser chip being used as an amplifier and the grating serving as a second facet. The last-mentioned structure of semiconductor laser diodes is also called external cavity diode laser (ECDL).

The afore-described methods and devices for mode selection of a semiconductor laser diode have the disadvantage that either only very limited ranges of the entire mode spectrum can be selected or that the provision of mechanical components has a particularly disadvantageous effect on the price and the system size of the corresponding lasers.

Moreover, there are other semiconductor laser diodes, such as semiconductor laser diodes having a so-called binary superimposed grating (BSG), which are capable of selecting a large range of the mode spectrum in a well-defined manner, but are very cost-intensive and time-consuming in terms of production and characterization of the laser diodes.

Providing a so-called integrated interdigital transducer (IDT) offers an inexpensive and highly efficient alternative for selectively choosing a specific emission wavelength from the mode spectrum of a semiconductor laser diode. The interdigital transducer excites a surface acoustic wave (SAW), which again leads to a periodic modulation of the refractive index in a layer adjacent to the interdigital transducer and thus allows a selective mode choice of the emission wavelength in a similar manner as in the afore-described options.

In this context, depending on their design, the known interdigital transducers exhibit a correspondingly narrow or broad resonance behavior, wherein the respective states of resonance can be excited in a correspondingly small frequency range by an externally supplied signal or by an alternating voltage. To be able to select the emission wavelength as broadly as possible in a corresponding laser or in a corresponding semiconductor laser diode, it may be accordingly provided that an interdigital transducer is basically designed in such a manner that it has a wide resonance band and the interdigital transducer is externally excited by a frequency band as narrow as possible or by a frequency as distinct as possible. A semiconductor laser diode of this kind is described in WO 2012/074382 A1, for example.

The known semiconductor laser diodes having a selectable or adjustable emission wavelength using an interdigital transducer have the disadvantage that success in generating and spreading or maintaining the surface acoustic wave in the area adjacent to the interdigital transducer or in the layer of the semiconductor laser diode adjacent to the interdigital transducer is poor or possible only to a small degree, causing the intended or desired modulation of the refractive index in said area or in said layer to take place in an equally poor manner or only to a small degree and thus to be overall insufficient, and, as a result, the adjustment or selection of an emission wavelength from the mode spectrum of the semiconductor laser diode is made possible or can be maintained only to a certain degree.

### DESCRIPTION OF FIGURES

The present invention will be explained in the following description by way of example with the aid of a merely schematic drawing.

In the drawing:

FIG. 1 shows a perspective view of a semiconductor laser diode according to the invention in a first embodiment example.

### DETAILED DESCRIPTION

Accordingly, it is the objective of the present invention to propose a semiconductor laser diode having a selectable or adjustable emission wavelength which overcomes the disadvantages of the state of the art as described above. This also means that the emission wavelength is dynamic, is adjustable during operation of the laser diode and is constant after adjustment, if desired. In other words, this means that the present invention seeks to develop further a generic semiconductor laser diode in such a manner that an effective and stable generation and maintenance of a surface acoustic wave by means of an interdigital transducer is made possible.

The objective is attained by a semiconductor laser diode according to the preamble of claim 1. Advantageous embodiments of the proposed semiconductor laser diode are the subject-matter of the dependent claims.

The present invention is based on the idea that a surface acoustic wave can be generated by means of an interdigital transducer in a layer adjacent to the interdigital transducer in a particularly favorable or effective manner if the layer adjacent to the interdigital transducer or the area adjacent to the interdigital transducer has particularly good piezoelectric properties. Since particularly good piezoelectric properties are achieved through a density of free charge carriers that is as low as possible or even zero, the basic idea of the present invention, in other words, lies in realizing the semiconductor laser diode in such a manner that a layer adjacent to an interdigital transducer or an area of such a layer is provided that has only a minimum amount of free charge carriers.

To that effect, it is provided that the semiconductor laser diode according to the invention has a substrate layer, a first doped cladding layer and a second doped cladding layer, at least one wave guide, an active layer, a cladding layer structure that is adjacent to the active layer or to the at least one wave guide, and at least one interdigital transducer, wherein the at least one interdigital transducer is adjacent to the cladding layer structure and the cladding layer structure has at least a first area that is realized as a substantially undoped semiconductor layer and has, at least in sections with respect to the first area, a second area that is adjacent to the first area at one side and to the interdigital transducer at another side, the second area having a reduced density of free charge carriers as compared to the first area.

It is to be stressed that, in the scope of the present invention, substantially undoped semiconductor layers are semiconductor layers that should basically not have any free charge carriers owing to the selected material and the desired production or deposition process, but still always have a certain amount of free charge carriers because of different phenomena, such as contaminations, faults or lattice defects, even if such semiconductor layers are generally called intrinsic semiconductor layers.

In other words, this means that, according to the semiconductor laser diode of the invention, a first area of the cladding layer structure is provided that can be generally called an intrinsic semiconductor layer and, at the same time, the second area, which is arranged at least in sections between the first area of the cladding layer structure and the interdigital transducer, has a once more significantly reduced density of free charge carriers as compared to the first area.

The semiconductor laser diode according to the invention makes it possible that the properties of the surface acoustic wave, which is generated by the interdigital transducer according to the corresponding excitation frequency, can be generated and maintained in a particularly effective and well-defined manner, thus allowing an equally highly effective and well-defined adjustment or selection of an individual emission wavelength from the mode spectrum of the semiconductor laser diode.

In this context, it may be provided within the scope of the invention that the second area of the cladding layer structure is made of an aluminous layer, in particular of an aluminum nitride layer. The use of an aluminous material for the second area of the cladding layer structure and in particular the use of an aluminous nitride layer is advantageous in that semiconductor layers of this kind have significantly improved piezoelectric properties compared with other intrinsic semiconductor layers or compound semiconductor layers. In other words, this means that the proposed advantageous layers also have a significantly reduced density of free charge carriers as compared to other intrinsic semiconductor layers or compound semiconductor layers.

For the second area of the cladding layer structure, materials are generally desirable that exhibit particularly high polarization when being mechanically deformed and a particularly high piezoelectric property since the surface acoustic wave of the interdigital transducer can be generated and maintained in these materials in a particularly effective manner. Hence, it may be preferred that the second layer of the cladding layer structure be made of zinc oxide (ZnO).

Layers of this kind can be easily integrated into the process flow in the production of a corresponding semiconductor laser diode and can be produced or deposited in a conventionally known manner. Another advantage of the aluminous layers and, more precisely, of the aluminum nitride layer in the second area of the cladding layer structure of the proposed semiconductor laser diode lies in the fact that their advantageous piezoelectric properties and the thus generated advantageous effect on the surface acoustic wave and the mode selection of the semiconductor laser diode depending on said surface acoustic wave can be realized irrespective of the other selection of the laser system and of the material selection of the laser system. Accordingly, the advantageous effects are system-independent and can thus be realized in a wealth of different semiconductor laser diodes having different outputs or other characteristics.

Within the scope of the proposed invention, it may also be provided that the second area is made of a semiconductor material, in particular of a III-V semiconductor material, and has a counter-doping. Counter-dopings of this sort are sufficiently known for the respective semiconductor materials or compound semiconductor materials and can be easily produced or deposited together with the actual semiconductor or compound semiconductor material in the scope of the method for producing the second area of the cladding layer structure.

For this purpose, methods such as molecular beam epitaxy or metalorganic gas phase epitaxy may be used, for example. One example for a cladding layer structure of this kind is an AlGaAsSb layer in the first area of the cladding layer structure, which has an intrinsic p-type doping, and a corresponding AlGaAsSb layer in the second area of the cladding layer structure, which is counter-doped with tellurium (Te) or silicon (Si) so as to improve the piezoelectric properties and to further reduce the density of free charge carriers as compared to the already basically intrinsic first area of the cladding layer structure. A cladding layer structure of this kind may be employed in a GaSb semiconductor laser diode system, for example, which is produced by means of molecular beam epitaxy.

In this context, it is particularly desirable that the first area of the cladding layer structure forms a major part or the largest part of the cladding layer structure and the second part or the part that has the counter-doping forms only little of the depth or thickness of the cladding layer structure. In the extreme case, the second area is formed merely as a barrier surface between the first area of the cladding layer structure and the adjacent interdigital transducer, said barrier surface being only thick or deep enough for the surface acoustic wave to be generated and maintained or guided. This is because the counter-doping in the second area of the cladding layer structure does positively influence the generation and maintenance of the surface acoustic wave, but at the same time it increases the electrical resistance in a disadvantageous manner.

Within the scope of the proposed invention, it may also be provided that the second area is made of a semiconductor material, in particular of a III-V semiconductor material, and has hydrogen atoms. The hydrogen atoms are intentionally introduced and, together with the present semiconductor materials, they form compounds and complexes via strong or weak covalent bonds.

The hydrogen atoms can be intentionally introduced by treating the cladding layer structure with hydrogen plasma or by another treatment with hydrogen radicals, for example. In a conventionally known manner, hydrogen radicals can be introduced into the second area of the cladding layer structure above a threshold temperature of the substrate and of the cladding layer structure, said hydrogen radicals then reacting to form corresponding hydrogen atoms so as to passivate free charge carriers by neutralization or complex formation of the doping atoms. The penetration depth of the hydrogen radicals and thus also the ratio between the first area of the cladding layer structure and the second area of the cladding layer structure can be determined by the duration of the exposure to the hydrogen radicals and by the correlated penetration depth of the hydrogen radicals.

In the scope of the present invention, it may also be provided for the proposed semiconductor laser diode that the first area of the cladding layer structure is made of a semiconductor material, in particular of a III-V semiconductor material. Materials of this kind are widespread in the production of corresponding semiconductor diodes and their handling is well-known and well-documented.

The proposed semiconductor laser diode may also be advantageously developed further in that the active layer has quantum dots. The previous semiconductor laser diodes, which provide a mode selection or an adjustment of the emission wavelength by means of an interdigital transducer, are designed such that the active layer has a quantum film. In contrast, however, the proposed quantum dots have the advantage that they make possible an active layer that allows amplitude modulation of the emission wavelength. Said amplitude modulation is an important factor in particular in signal transmission. Accordingly, the proposed semiconductor laser diode can simultaneously permit a modulation of the emission wavelength and a mode selection from the mode spectrum as well as an amplitude modulation, which in total leads to a highly advantageous and thus desirable character or potential characteristics of the semiconductor laser diode.

In the scope of the present invention, it may be additionally advantageous if the active layer has quantum dashes. In this manner, too, an amplitude modulation in the active layer is made possible, which is accompanied by the afore-described advantages of a semiconductor laser diode of this kind.

Other advantages of the present invention can also be achieved in that the active layer has semiconductor materials or layers that are formed by said semiconductor materials and have only one kind of doping. Semiconductor laser diodes of this sort having only one kind of doping in the active layer can be formed as interband cascade lasers or quantum cascade lasers, for example, which offer special advantages on their part and which can be combined in an additional particularly advantageous manner with the afore-described advantages of the invention, such as, in particular, the improved adjustability of the emission wavelength and mode selection, and the thus achieved definition of the emission wavelength. For example, but by no means exclusively, active layers having semiconductor materials and layers having only one kind of doping can have different n-type dopings or semiconductor materials with different n-type dopings.

It may also be advantageous for the proposed semiconductor laser diode if the at least one interdigital transducer is realized as a comb-like structure. In this way, corresponding resonance characteristics and a corresponding resonance behavior of the interdigital transducers can be predicted and realized in a particularly simple and advantageous manner.

It may also be particularly advantageous for the proposed semiconductor laser diode if the at least one interdigital transducer has a conductive material, in particular gold. Thus, it becomes possible to generate and maintain the surface acoustic wave in an especially effective manner.

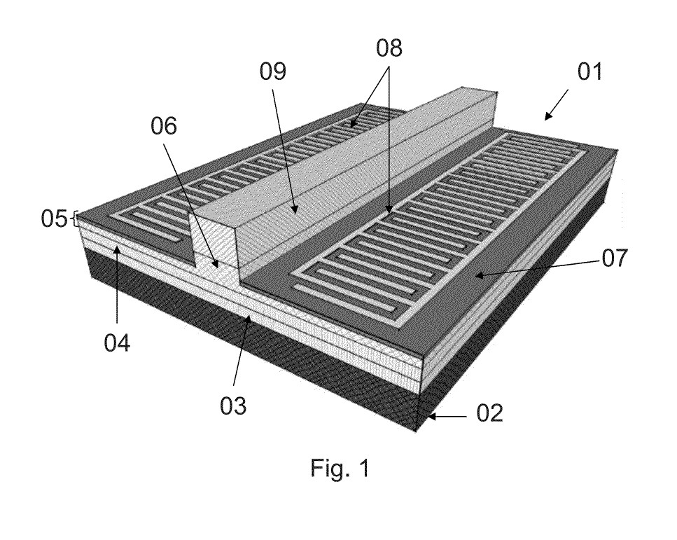

FIG. 1 shows a semiconductor laser diode 01 that has an n-type cladding layer 02 on a substrate (not illustrated). An n-type cladding layer is to be understood as an n-doped cladding layer in this case. Above the n-type cladding layer 02, an active layer is indicated, which is arranged as a barrier surface or as a borderline between the wave guides 03 and 04. The cladding layer structure 05 is applied to the top side of the wave guide 04. The cladding layer structure 05 has a first area 06 and, at least in sections, a second area 07. Two interdigital transducers 08 are located above the cladding layer structure 05, each above the area of the cladding layer structure, which has a first and a second area. Between the interdigital transducers 08, the cladding layer structure 05 has only a first area 06, which is adjacent to a p-type cladding layer 09. In the meaning of this description, a p-type cladding layer is to be understood as a p-doped cladding layer of the semiconductor laser diode.

In the example of FIG. 1, the second area 07 of the cladding layer structure 05 can be made of aluminum nitride, for example, which has the result that the surface acoustic wave, which is generated by means of the interdigital transducers 08, can be excited and maintained in a particularly well-defined manner. Thus, again, a modulation of the refractive index in the cladding layer structure 05 is achieved, which allows a both well-defined adjustment or selection of a mode of the mode spectrum of the Fabry-Perot modes comprised by the gain bandwidth of the semiconductor laser diode 01 and a correspondingly selective choice of an emission wavelength of the semiconductor laser diode 01.

However, the sequence of the layer structure illustrated in FIG. 1 is by no means binding. For example, it may also be provided that the at least one interdigital transducer is arranged between the n-type cladding layer 02 and a cladding layer structure, to which the active layer and the wave guide are adjacent from above.

1. A semiconductor laser diode comprising:
a substrate layer, a first doped cladding layer and a second doped cladding layer, at least one wave guide, an active layer, a cladding layer structure that is adjacent to the active layer or to the at least one wave guide, and at least one interdigital transducer,
wherein the at least one interdigital transducer is adjacent to the cladding layer structure and the cladding layer structure has at least a first area that is realized as a substantially undoped semiconductor layer and has, at least in sections, a second area that is adjacent to the first area at one side and to the interdigital transducer at another side, the second area having a reduced density of free charge carriers as compared to the first area.

2. The semiconductor laser diode according to claim 1, wherein the second area is made of an aluminous layer, in particular of an aluminum nitride layer (AIN layer).

3. The semiconductor laser diode according to claim 1, wherein the second area is made of zinc oxide (ZnO).

4. The semiconductor laser diode according to claim 1, wherein the second area is made of a semiconductor material, in particular of a III-V semiconductor material, and has a counter-doping.

5. The semiconductor laser diode according to claim 1, wherein the second area is made of a semiconductor material, in particular of a III-V semiconductor material, and has hydrogen atoms.

6. The semiconductor laser diode according to claim 1, wherein the first area is made of a semiconductor material, in particular of a III-V semiconductor material.

7. The semiconductor laser diode according to claim 1, wherein the active layer has quantum dots.

8. The semiconductor laser diode according to claim 1, wherein the active layer has quantum dashes.

9. The semiconductor laser diode according to claim 1, wherein the active layer has semiconductor materials that have only one kind of doping.

10. The semiconductor laser diode according to claim 1, wherein the at least one interdigital transducer is realized as a comb-like structure.

11. The semiconductor laser diode according to claim 1, wherein the at least one interdigital transducer has a conductive material, in particular gold.
